(19) United States
(12) Patent Application Publication
(10) Pub. No.: US 2018/0059744 A1
(43) Pub. Date: Mar. 1, 2018

(54) LIQUID COOLING INTERFACE FOR FIELD REPLACEABLE ELECTRONIC COMPONENT

(71) Applicant: Intel Corporation, Santa Clara, CA (US)

(72) Inventors: MICHAEL S. BRAZEL, Federal Way, WA (US); BARRETT M. FANEUF, Beaverton, OR (US); TOD A. BYQUIST, Federal Way, WA (US); EMERY E. FREY, Portland, OR (US); JUAN G. CEVALLOS, Portland, OR (US)

(21) Appl. No.: 15/246,329

(22) Filed: Aug. 24, 2016

(51) Int. Cl. G06F 1/20; H05K 7/20; G06F 1/18

(52) U.S. Cl. CPC G06F 1/20; G06F 1/183; H05K 7/20336

(57) ABSTRACT

Embodiments herein relate to liquid cooling interfaces for field replaceable electronic components. An apparatus for cooling a computer device may include a cooling component coupled with an existing cooling system and a connector coupled with the cooling component, where the connector may be structured to removably couple the liquid cooling block to a heat conductor of a field replaceable electronic component when the field replaceable electronic component is inserted into a computer device. In some embodiments, the connector may be a clamp structured to receive the heat conductor during insertion of the field replaceable electronic component along a plane, and to provide a clamping force orthogonal to the plane. Other embodiments may be described and/or claimed.

### FIELD

Embodiments of the present disclosure generally relate to the field of computer component cooling and, more particularly, to liquid cooling interfaces for electronic component cooling.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

The High Performance Compute (HPC) industry is moving toward thinner and more tightly packaged products for energy efficiency and compute power. These high density, thin server products may not have sufficient airflow to support adequate air cooled solutions for some components. Typically, memory modules and other replaceable electronic components in computers rely on air cooled solutions and/or dedicated self-contained water cooled solutions. With more tightly packaged products, air cooling may not be adequate and self-contained water cooled solutions may not allow for easy field replacement of the component being cooled.

### BRIEF DESCRIPTION OF THE DRAWINGS

Embodiments of the liquid cooling interface for field replaceable electronic components of the present disclosure may overcome these limitations. The embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an apparatus for cooling a computer device, partially coupled with a memory module assembly, according to various embodiments.

FIG. 2 illustrates a top view of a clamp assembly, according to various embodiments.

FIG. 3 illustrates a partial schematic view of a computer device with an apparatus for cooling the computer device, according to various embodiments.

FIG. 4 schematically illustrates a cross-sectional view of a portion of a clamp assembly, according to various embodiments.

FIG. 5A illustrates a cooling block clamp assembly in an open position, according to various embodiments.

FIG. 5B illustrates the cooling block assembly of FIG. 5A in a closed position, according to various embodiments.

FIG. 6 schematically illustrates an example computing device including an apparatus for cooling the computing device, according to various embodiments.

FIGS. 7A and 7B illustrate a cooling assembly that uses a flexible conductor, according to various embodiments.

### DETAILED DESCRIPTION

Embodiments of the present disclosure describe liquid cooling interfaces for field replaceable electronic components. In various embodiments, an apparatus for cooling a computer device may include a cooling component coupled with an existing cooling system and a connector coupled with the cooling component. In some embodiments, the cooling component may be a liquid cooling block and the connector may be a clamp structured to removably couple the liquid cooling block to a heat conductor of a field replaceable electronic component when the field replaceable electronic component is inserted into a computer device. In some embodiments, the heat conductor may extend from the field replaceable electronic component and the clamp may be structured to receive the heat conductor during insertion of the field replaceable electronic component along a plane, and to provide a clamping force orthogonal to the plane.

Various embodiments may employ a system approach to cooling dual in-line memory modules (DIMMs) using heat spreaders, heat pipes, and cold plates tied directly to a system fluid network. In some embodiments, a cooling solution may include a tightly packaged assembly built around the DIMM, utilizing a hinging thermal interface feature, so that the DIMM can be cooled while offering an improved maintenance/serviceability model. In various embodiments, combining the cooling solution into a system assembly may increase the speed of replacement and/or reduce the cost for maintenance of a field replaceable unit (FRU) such as a DIMM, while maximizing the heat transfer efficiency.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. It will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

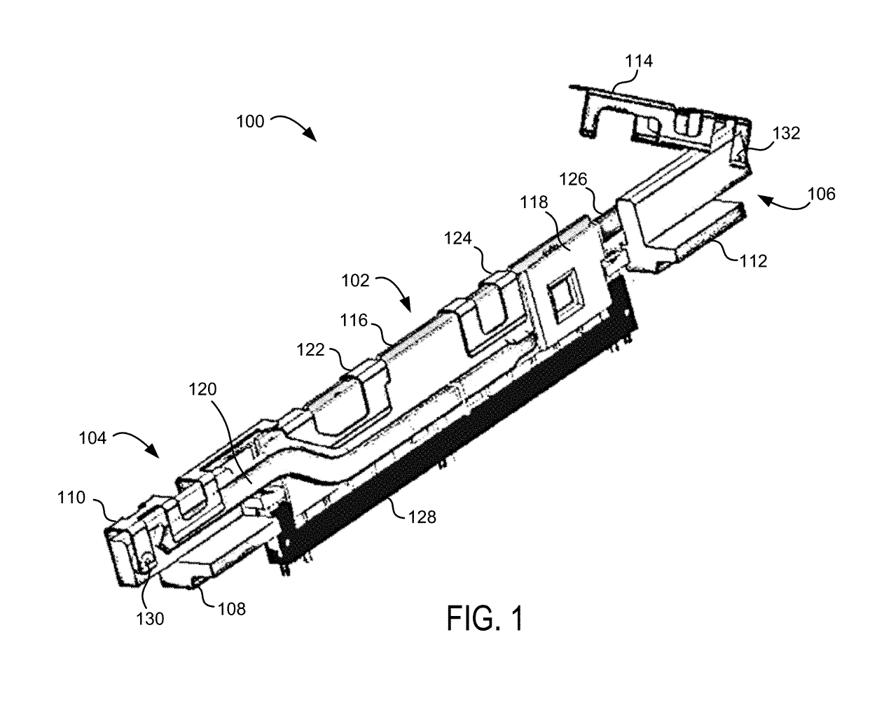

FIG. 1 illustrates an apparatus 100 for cooling a computer device, according to various embodiments. The apparatus 100 is shown partially coupled with a memory module assembly 102, according to some embodiments. In various embodiments, the apparatus 100 may include a first clamp assembly 104 and a second clamp assembly 106. In various embodiments, the first clamp assembly 104 may include a first liquid cooling block 108 and a first clamp 110 coupled with the first liquid cooling block 108. In some embodiments, the second clamp assembly 106 may include a second liquid cooling block 112 and a second clamp 114 coupled with the second liquid cooling block 112. In various embodiments, the memory module assembly 102 may include a memory module 116 such as a dual in-line memory module (DIMM), a cooling plate 118, a heat conductor such as a first heat pipe 120 coupled with the cooling plate 118 and extending from the memory module 116, a first clip 122, and a second clip 124 to hold the cooling plate 118 to the memory module 116. In some embodiments, the first clip 122 and the second clip 124 may also hold another cooling plate to another side of the memory module 116, and a second heat pipe 126 coupled with the other cooling plate may extend from the other side of the memory module 116. In various embodiments, the memory module 116 may be inserted into a connector 128 along an insertion plane. In some embodiments, the connector 128 may be a receptacle such as a slot to receive a field replaceable electronic component having a card edge connector, such as the memory module 116.

In various embodiments, the memory module assembly 102 may include a device connector such as a card edge connector structured to be removably accepted into a receptacle of a motherboard such as the connector 128 along the insertion plane. In some embodiments, the first heat pipe 120 and the second heat pipe 126 may be heat conductors structured to be received by a cooling connector (e.g., first clamp 110, second clamp 114) that is to removably couple, with a clamping force orthogonal to the plane, the heat conductor to a cooling component (e.g., first liquid cooling block 108, second liquid cooling block 112) coupled with an existing cooling system.

The first clamp 110 is shown in a closed position and the second clamp 114 is shown in a partially open position. In various embodiments, the first clamp 110 may be hinged about a first rotational axis 130 orthogonal to the insertion plane and coupled with the first liquid cooling block 108 at the first rotational axis 130. In some embodiments, the second clamp 114 may be hinged about a second rotational axis 132 orthogonal to the insertion plane and coupled with the second liquid cooling block 112 at the second rotational axis 132. In some embodiments, the first clamp 110 may rotate about the first rotational axis 130 when moving from an open position to a closed position and the second clamp 114 may rotate about the second rotational axis 132 when moving from an open position to a closed position.

In various embodiments, the first clamp 110 and the second clamp 114 may be structured to removably couple the first liquid cooling block 108 with the first heat pipe 120 and the second liquid cooling block 112 with the second heat pipe 126, respectively. The first clamp 110 may provide a clamping force orthogonal to the insertion plane to clamp the first heat pipe 120 between an inner clamp side of the first clamp 110 and the first liquid cooling block 108, and the second clamp 114 may provide a clamping force orthogonal to the insertion plane to clamp the second heat pipe 126 between an inner clamp side of the second clamp 114 and the second liquid cooling block 112, according to various embodiments. In some embodiments, coupling the first liquid cooling block 108 and the second liquid cooling block 112 to heat conductors extending from a field replaceable electronic component by providing a clamping force in a direction orthogonal to an insertion plane may reduce a z-height of cooling components in a computer device, allowing the apparatus to fit in an enclosure having a relatively small height, such as a one rack unit (1U) enclosure. In various embodiments, a thermal interface material (TIM) may be between the first heat pipe 120 and the first liquid cooling block 108 and/or between the second heat pipe 126 and the second liquid cooling block 112. In some embodiments, the clamping force provided by the first clamp 110 and/or the second clamp 114 may create a thinner TIM bond line while maximizing surface area and heat transfer to a system fluid network by compressing the TIM between the first heat pipe 120 and the first liquid cooling block 108 and/or the TIM between the second heat pipe 126 and the second liquid cooling block 112. In various embodiments, the TIM bond line may have a thickness in a range from approximately 0.25 millimeters (mm) to approximately 0.75 mm. The TIM bond line may have a different thickness in other embodiments.

In some embodiments, although not shown for clarity, the first liquid cooling block 108 and the second liquid cooling block 112 may each include a liquid inlet port and a liquid outlet port. In various embodiments, the liquid outlet port of the first liquid cooling block 108 may be coupled with the liquid inlet port of the second liquid cooling block 112. In various embodiments, the first liquid cooling block 108 and/or the second liquid cooling block 112 may not include a liquid inlet port and a liquid outlet port, instead being thermally coupled in another manner with a system liquid cooling network, such as by being soldered to a component of the system liquid cooling network. In some embodiments, the first clamp 110 and the second clamp 114 may each be structured to include a finger grip to provide for simplified tool-less opening by a user. In various embodiments, the first clamp 110 and/or the second clamp 114 may be coupled with the first liquid cooling block 108 and the second liquid cooling block 112, respectively, as a captured clip to eliminate loose parts and provide for tool-less installation of a field replaceable electronic component.

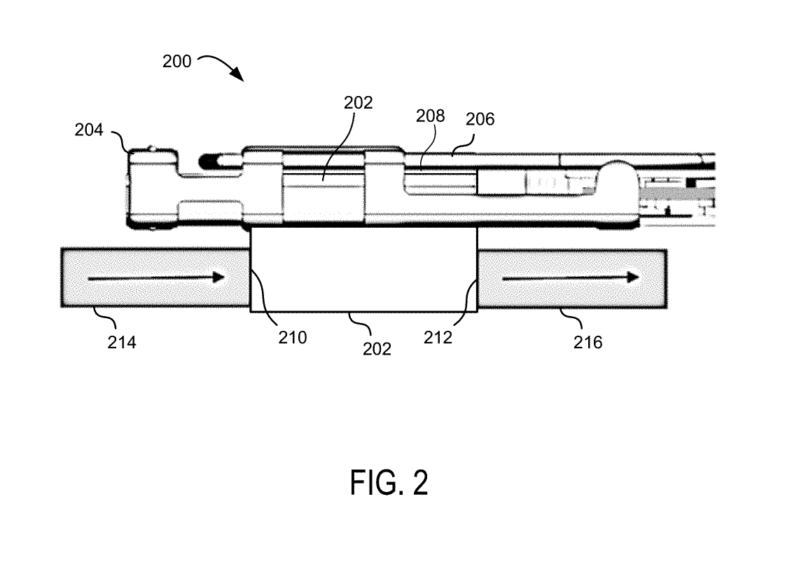

FIG. 2 illustrates a top view of a clamp assembly 200, according to various embodiments. In some embodiments, the clamp assembly 200 may be structured in similar fashion to the first clamp assembly 104 or the second clamp assembly 106 described with respect to FIG. 1. In various embodiments, the clamp assembly 200 may include a liquid cooling block 202 and a clamp 204 coupled with the liquid cooling block 202. In some embodiments, the clamp 204 may be used to couple a heat conductor such as a heat pipe 206 to the liquid cooling block 202. In various embodiments, a thermal interface material (TIM) 208 may be compressed between the heat pipe 206 and the liquid cooling block 202 when the clamp 204 is in a closed position coupling the heat pipe 206 to the liquid cooling block 202. In some embodiments, the liquid cooling block 202 may include an inlet port 210 and an outlet port 212. A first fluid conductor 214, such as a tube, may be coupled with the inlet port 210 and a second fluid conductor 216 may be coupled with the outlet port 212, in various embodiments.

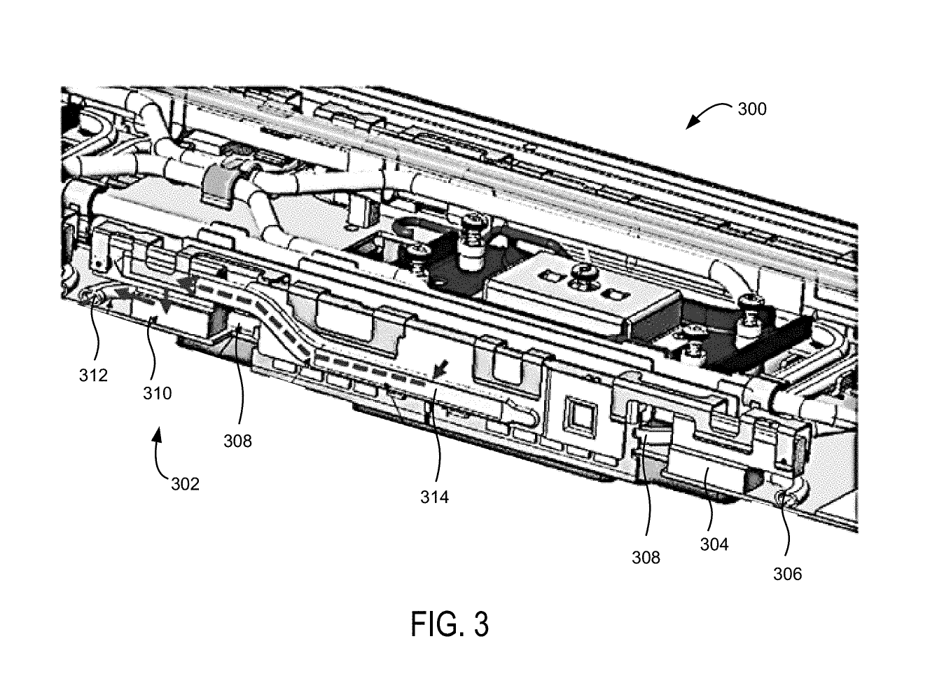

FIG. 3 illustrates a partial schematic view of a computer device 300 with an apparatus 302 for cooling the computer device 300, according to various embodiments. In some embodiments, the computer device 300 may be one rack unit (1U) high such that a height of the apparatus 302 is no more than 1.75 inches in order to fit within the 1U dimension of the computer device 300. In some embodiments, the apparatus 302 may be structured in similar fashion to the apparatus 100 depicted in FIG. 1. In various embodiments, the apparatus 302 may include a first liquid cooling block 304 having an inlet port coupled with a first fluid conductor 306 and an outlet port coupled with a second fluid conductor 308. In some embodiments, the apparatus 302 may also include a second liquid cooling block 310 having an inlet port coupled with the second fluid conductor 308 and an outlet port coupled with a third fluid conductor 312. In various embodiments, the first fluid conductor 306 may be coupled with a computer device liquid inlet port such that the inlet port of the first liquid cooling block 304 may be coupled with the computer device liquid inlet port. In some embodiments, the third fluid conductor 312 may be coupled with a computer device liquid outlet port such that the outlet port of the second liquid cooling block 310 may be coupled with the computer device liquid outlet port.

A heat conductor, such as a heat pipe 314, may be coupled with the second liquid cooling block 310 with a clamp in similar fashion as that described with respect to FIG. 1. In various embodiments, heat may flow along a heat path through the heat pipe 314, into the second liquid cooling block 310, and into a fluid carried by the third fluid conductor 312. In some embodiments, a liquid such as water may flow through the first fluid conductor 306 into the inlet port of the first liquid cooling block 304, out of the outlet port of the first liquid cooling block 304 into the second fluid conductor 308, into the inlet port of the second liquid cooling block 310, and out of the outlet port of the second liquid cooling block 310 into the third fluid conductor 312.

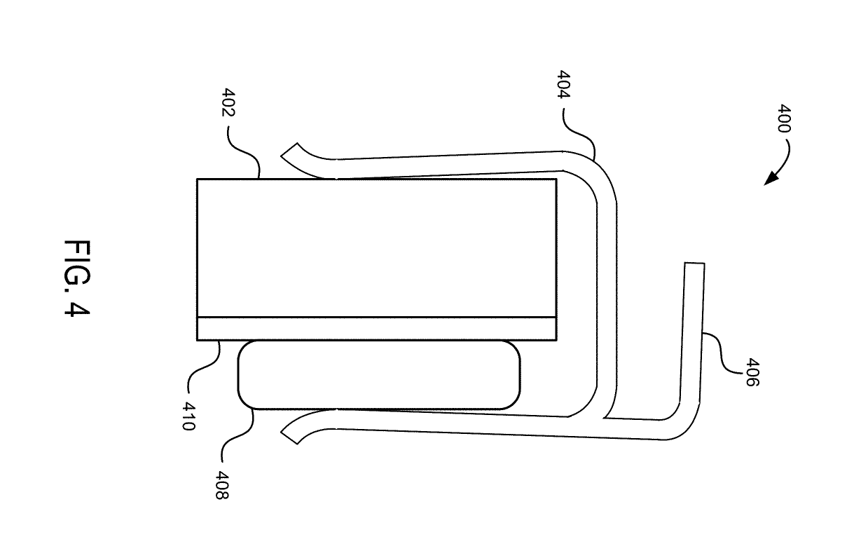

FIG. 4 schematically illustrates a cross-sectional view of a portion of a clamp assembly 400, according to various embodiments. In some embodiments, the clamp assembly 400 may include a liquid cooling block 402 and a clamp 404 coupled with the liquid cooling block 402. The clamp 404 may be structured to include a finger grip 406, in various embodiments. The clamp 404 is shown in a closed position, coupling a heat pipe 408 with the liquid cooling block 402. In some embodiments, a TIM 410 may be located between the heat pipe 408 and the liquid cooling block 402 when the heat pipe 408 is coupled with the liquid cooling block 402. In various embodiments, the TIM 410 may be a thermal pad coupled with the heat pipe 408, thermal grease, or some other type of TIM.

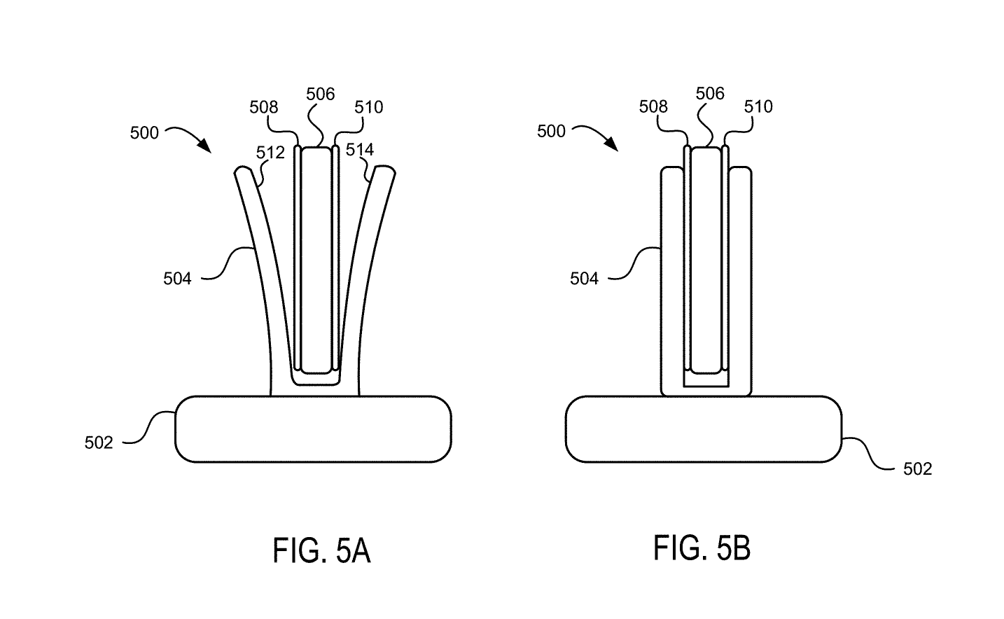

FIG. 5A illustrates a cooling block clamp assembly 500 in an open position and FIG. 5B illustrates the cooling block clamp assembly 500 in a closed position, according to various embodiments. In some embodiments, the cooling block clamp assembly 500 may include a cooling block 502 and a clamp 504 coupled with the cooling block 502. In various embodiments, the cooling block 502 may be a liquid cooling block having an inlet port and an outlet port. A heat conductor 506, such as a heat pipe, may have a first TIM layer 508 on a first side and a second TIM layer 510 on a second side of the heat conductor 506. In some embodiments, the clamp 504 may be a U-shaped channel having a first, closed end, coupled with the cooling block 502 and a second, open end, opposite the first end, to removably receive the heat conductor 506 and provide an inward clamping force orthogonal to a direction of insertion of the heat conductor from the open end to the closed end.

In various embodiments, the clamp 504 may include a first inner side 512 and a second inner side 514. In some embodiments, the inward clamping force exerted by the clamp 504 may compress the first TIM layer 508 between the first inner side 512 and the first side of the heat conductor 506, and may compress the second TIM layer 510 between the second inner side 514 and the second side of the heat conductor 506. In various embodiments, the cooling block clamp assembly 500 may be positioned proximate a connector (e.g., connector 128) in similar fashion to the first clamp assembly 104 and/or the second clamp assembly 106 described with respect to FIG. 1, to removably receive a heat conductor when a field replaceable electronic component such as a memory module is coupled with the connector.

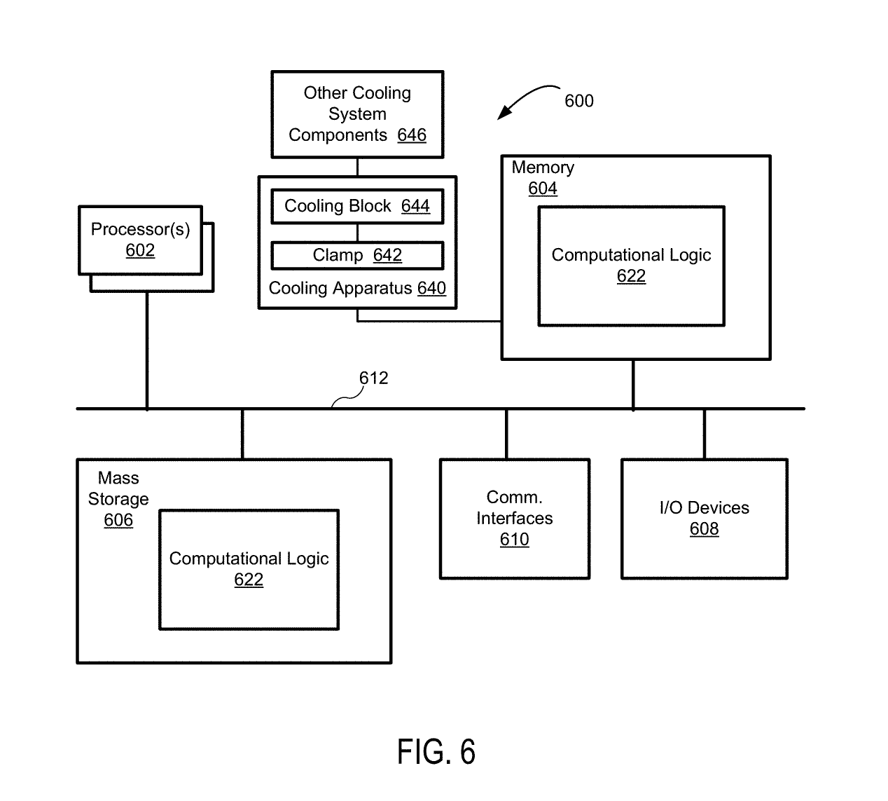

FIG. 6 illustrates an example computing device 600 that may be cooled by various components of FIGS. 1-5, such as apparatus 100 described with respect to FIG. 1, clamp assembly 200 described with respect to FIG. 2, apparatus 302 described with respect to FIG. 3, clamp assembly 400 described with respect to FIG. 4, and/or cooling block clamp assembly 500 described with respect to FIG. 5, in accordance with various embodiments. As shown, computing device 600 may include one or more processors or processor cores 602 and system memory 604. For the purpose of this application, including the claims, the terms “processor” and “processor cores” may be considered synonymous, unless the context clearly requires otherwise. The processor 602 may include any type of processors, such as a central processing unit (CPU), a microprocessor, and the like. The processor 602 may be implemented as an integrated circuit having multi-cores, e.g., a multi-core microprocessor. The computing device 600 may include mass storage devices 606 (such as diskette, hard drive, volatile memory (e.g., dynamic random-access memory (DRAM), compact disc read-only memory (CD-ROM), digital versatile disk (DVD), and so forth). In general, system memory 604 and/or mass storage devices 606 may be temporal and/or persistent storage of any type, including, but not limited to, volatile and non-volatile memory, optical, magnetic, and/or solid state mass storage, and so forth. Volatile memory may include, but is not limited to, static and/or dynamic random access memory. Non-volatile memory may include, but is not limited to, electrically erasable programmable read-only memory, phase change memory, resistive memory, and so forth.

The computing device 600 may further include input/output devices 608 (such as a display (e.g., a touchscreen display), keyboard, cursor control, remote control, gaming controller, image capture device, and so forth) and communication interfaces 610 (such as network interface cards, modems, infrared receivers, radio receivers (e.g., Bluetooth), and so forth). The computing device 600 may include a cooling apparatus 640 (e.g., apparatus 100, apparatus 302) that may include a clamp 642 coupled with a cooling block 644 (e.g., clamp 110 coupled with liquid cooling block 108, clamp 114 coupled with liquid cooling block 112, clamp 204 coupled with liquid cooling block 202, a clamp coupled with cooling block 304 or 310, clamp 404 coupled with a cooling block, and/or clamp 504 coupled with cooling block 502). In various embodiments, the cooling apparatus 640 may be coupled with other cooling system components (e.g., first fluid conductor 214, second fluid conductor 216, first fluid conductor 306, second fluid conductor 308, and/or third fluid conductor 312). In some embodiments, the cooling apparatus 640 may be removably coupled with a field replaceable electronic component such as the memory 604. In various embodiments, the cooling apparatus 640 may be removably coupled with some other type of field replaceable electronic component.

The communication interfaces 610 may include communication chips (not shown) that may be configured to operate the device 600 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 610 may operate in accordance with other wireless protocols in other embodiments. In some embodiments, the communication interfaces 610 may operate in accordance with one or more wired network protocols or technologies such as Ethernet (e.g., Institute of Electrical and Electronics Engineers (IEEE) standard 802.3) or some other wired network protocol or technology.

The above-described computing device 600 elements may be coupled to each other via system bus 612, which may represent one or more buses. In the case of multiple buses, they may be bridged by one or more bus bridges (not shown). Each of these elements may perform its conventional functions known in the art. The various elements may be implemented by assembler instructions supported by processor(s) 602 or high-level languages that may be compiled into such instructions.

The permanent copy of the programming instructions may be placed into mass storage devices 606 in the factory or in the field through, for example, a distribution medium (not shown), such as a compact disc (CD), or through communication interface 610 (from a distribution server (not shown)). That is, one or more distribution media having an implementation of the agent program may be employed to distribute the agent and to program various computing devices.

The number, capability, and/or capacity of the elements 608, 610, 612 may vary, depending on whether computing device 600 is used as a stationary computing device, such as a set-top box or desktop computer, or a mobile computing device, such as a tablet computing device, laptop computer, game console, or smartphone. Their constitutions are otherwise known, and accordingly will not be further described.

For some embodiments, at least one of processors 602 may be packaged together with all or portions of computational logic 622 configured to facilitate aspects of embodiments described herein to form a System in Package (SiP) or a System on Chip (SoC).

In various implementations, the computing device 600 may comprise one or more components of a server, a high performance computing device, a desktop computer, a data center, or a laptop computer. In further implementations, the computing device 600 may be any other electronic device that processes data.

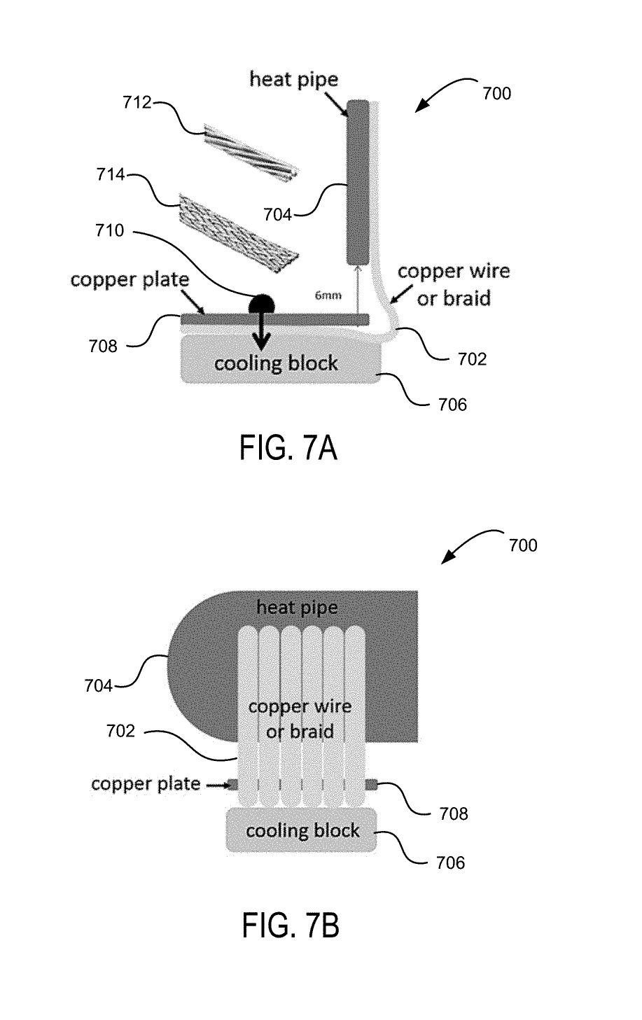

FIG. 7A illustrates a cooling assembly 700 that uses a flexible conductor 702 in accordance with some embodiments. FIG. 7B illustrates another view of the cooling assembly 700, in accordance with some embodiments. In various embodiments, a first portion of the flexible conductor 702 may be coupled with a heat conductor 704 (e.g.,) and a second portion of the flexible conductor 702 may be coupled with both a cooling component 706 such as a liquid cooling block. In some embodiments, a copper plate 708 may be used to couple the flexible conductor 702 to the cooling component 706. A screw 710 or other fastener may be used to couple the copper plate 708 to the cooling component 706 in various embodiments. An example wire 712 and an example braid 714 are shown such as may be used for the flexible conductor 702 in various embodiments. In some embodiments, a distance between the cooling component 702 and a lower edge of the heat conductor 704 may be approximately 6 millimeters. The distance may be different in other embodiments.

In some embodiments, the cooling assembly 700 may be used with a DIMM sandwiched with two heat pipe integrated cooling plates. In embodiments, the heat pipes may extend past the edge of the memory module and the end of the heat pipes may have a copper grounding braid soldered to it. In some embodiments, an existing system liquid cooling network may have a cooling block soldered to it and the copper braid may be attached via a copper plate soldered to the copper braid with a screw through the cooling block providing an efficient heat path to the system liquid cooling network. In various embodiments, the flexible copper braid may offer flex and take up the z-stack tolerance while minimizing the conduction path between the heat pipe and the system fluid network. In some embodiments, other types of flexible heat spreaders such as graphene sheet may be used instead of or in addition to the copper braid for the flexible conductor 702. In some embodiments, another type of metal or some other thermally conductive material may be used for the flexible heat conductor 702. In various embodiments, the copper plate 708 may be formed of a different material, such as a different metal or other thermally conductive material.

### EXAMPLES

Example 1 may include an apparatus for cooling a computer device comprising: a cooling component coupled with an existing cooling system; and a connector coupled with the cooling component, wherein the connector is structured to removably couple the cooling component to a heat conductor of a field replaceable electronic component when the field replaceable electronic component is inserted into a computer device.

Example 2 may include the subject matter of Example 1, wherein the connector is structured to receive the heat conductor during insertion of the field replaceable electronic component along a plane, and to provide a clamping force orthogonal to the plane.

Example 3 may include the subject matter of any one of Examples 1-2, wherein the connector is a clamp, the cooling component is a liquid cooling block, and the clamp is structured to clamp the heat conductor between an inner clamp side and the liquid cooling block.

Example 4 may include the subject matter of any one of Examples 2-3, wherein the clamp is hinged about a rotational axis orthogonal to the plane such that the clamp rotates about the rotational axis when moving from an open position to a closed position.

Example 5 may include the subject matter of Example 4, wherein the clamp is coupled with the liquid cooling block at the rotational axis.

Example 6 may include the subject matter of any one of Examples 1-5, wherein the clamp includes a finger grip.

Example 7 may include the subject matter of any one of Examples 1-6, wherein the cooling component is a liquid cooling block that includes a liquid inlet port and a liquid outlet port.

Example 8 may include the subject matter of any one of Examples 1-7, wherein the cooling component is a first liquid cooling block, the connector is a first clamp, the heat conductor is a first heat conductor, and the apparatus further includes: a second liquid cooling block; and a second clamp coupled with the second liquid cooling block, wherein the second clamp is structured to removably couple the second liquid cooling block to a second heat conductor that extends from the field replaceable electronic component.

Example 9 may include the subject matter of Example 8, wherein: the first liquid cooling block includes a first liquid inlet port and a first liquid outlet port; the second liquid cooling block includes a second liquid inlet port and a second liquid outlet port; and the first liquid outlet port is coupled with the second liquid inlet port.

Example 10 may include the subject matter of any one of Examples 1-9, wherein the field replaceable electronic component is a memory module and the heat conductor is a heat pipe.

Example 11 may include the subject matter of any one of Examples 1-10, wherein the heat conductor extends from the field replaceable electronic component.

Example 12 may include the subject matter of any one of Examples 1-2, wherein the cooling component is a liquid cooling block and the connector is a clamp having a first, closed end, coupled with the liquid cooling block and a second, open end, opposite the first end, to removably receive the heat conductor and provide an inward clamping force orthogonal to a direction of insertion of the heat conductor from the open end to the closed end.

Example 13 may include the subject matter of Example 12, wherein the clamp is a u-shaped channel structured to thermally couple a first side of the heat conductor with a first inner side of the u-shaped channel and a second side of the heat conductor with a second inner side of the u-shaped channel.

Example 14 may include the subject matter of Example 13, wherein the inward clamping force is to compress a thermal interface material between the first side of the heat conductor and the first inner side, and between the second side of the heat conductor and the second inner side.

Example 15 may include the subject matter of any one of Examples 1-14, further comprising the computer device having the electronic component inserted.

Example 16 may include a computer device comprising: a networking interface; a processor coupled with the networking interface; an electronic component coupled with the processor, wherein the electronic component is field replaceable; a receptacle to removably receive and electrically couple the field replaceable electronic component; a cooling component coupled with an existing cooling system; and a connector coupled with the cooling component, wherein the connector is structured to removably couple the cooling component to a heat conductor of the field replaceable electronic component.

Example 17 may include the subject matter of Example 16, wherein the heat conductor extends from the field replaceable electronic component and the connector is a clamp positioned to receive the heat conductor during insertion of the field replaceable electronic component into the receptacle along a plane, and structured to provide a clamping force orthogonal to the plane.

Example 18 may include the subject matter of any one of Examples 16-17, wherein the receptacle is a slot to receive a field replaceable electronic component having a card edge connector.

Example 19 may include the subject matter of Example 18, wherein the slot is a dual in-line memory module (DIMM) slot.

Example 20 may include the subject matter of any one of Examples 16-19, wherein the cooling component is a liquid cooling block that includes a liquid inlet port and a liquid outlet port.

Example 21 may include the subject matter of Example 20, wherein the liquid cooling block liquid inlet port is coupled with a computer device liquid inlet port and the liquid cooling block liquid outlet port is coupled with a computer device liquid outlet port.

Example 22 may include an apparatus for cooling a computer device comprising: means for thermally coupling a cooling component in a computer device to an existing cooling system; and means for removably coupling, in a tool-less manner, a heat conductor of a field replaceable electronic component to the cooling component.

Example 23 may include the subject matter of Example 22, wherein the cooling component is a liquid cooling block and the means for removably coupling the heat conductor to the liquid cooling block includes means for compressing a thermal interface material between the heat conductor and the liquid cooling block.

Example 24 may include the subject matter of any one of Examples 22-23, wherein the cooling component is a liquid cooling block, the heat conductor extends from the field replaceable electronic component, and the means for removably coupling the heat conductor to the liquid cooling block is structured to receive the heat conductor during insertion of the field replaceable electronic component along a plane, and to provide a clamping force orthogonal to the plane.

Example 25 may include the subject matter of any one of Examples 22-24, further comprising means for rotationally coupling the means for removably coupling the heat conductor to the liquid cooling block to the liquid cooling block such that the means for removably coupling the heat conductor rotates about an axis orthogonal to the plane when moving from an open to a closed position.

Example 26 may include a field replaceable electronic device comprising: a device connector structured to be removably accepted into a receptacle of a motherboard along a plane; and a heat conductor structured to be received by a cooling connector that is to removably couple, with a clamping force orthogonal to the plane, the heat conductor to a cooling component coupled with an existing cooling system.

Example 27 may include the subject matter of Example 26, wherein the device connector is a card edge connector, the heat conductor extends from the field replaceable electronic device, the cooling connector is a clamp, and the cooling component is a liquid cooling block.

Example 28 may include the subject matter of any one of Examples 26-27, wherein the field replaceable electronic device is a dual inline memory module (DIMM).

Example 29 may include the subject matter of any one of Examples 26-28, wherein the heat conductor is a heat pipe.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus for cooling a computer device comprising:
a cooling component coupled with an existing cooling system; and
a connector coupled and in contact with the cooling component, wherein the connector is structured to removably couple the cooling component to a heat conductor of a field replaceable electronic component when the field replaceable electronic component is inserted into a computer device, and wherein the connector is structured to remain coupled with the cooling component when the field replaceable electronic component is removed.

2. The apparatus of claim 1, wherein the connector is structured to receive the heat conductor during insertion of the field replaceable electronic component along a plane, and to provide a clamping force orthogonal to the plane.

3. The apparatus of claim 2, wherein the connector is a clamp, the cooling component is a liquid cooling block, and the clamp is structured to clamp the heat conductor between an inner clamp side and the liquid cooling block.

4. The apparatus of claim 3, wherein the clamp is hinged about a rotational axis orthogonal to the plane such that the clamp rotates about the rotational axis when moving from an open position to a closed position.

5. The apparatus of claim 4, wherein the clamp is coupled with the liquid cooling block at the rotational axis.

6. The apparatus of claim 4, wherein the clamp includes a finger grip.

7. The apparatus of claim 1, wherein the cooling component is a liquid cooling block that includes a liquid inlet port and a liquid outlet port.

8. The apparatus of claim 1, wherein the cooling component is a first liquid cooling block, the connector is a first clamp, the heat conductor is a first heat conductor, and the apparatus further includes:
a second liquid cooling block; and
a second clamp coupled with the second liquid cooling block, wherein the second clamp is structured to removably couple the second liquid cooling block to a second heat conductor that extends from the field replaceable electronic component.

9. The apparatus of claim 8, wherein:
the first liquid cooling block includes a first liquid inlet port and a first liquid outlet port;
the second liquid cooling block includes a second liquid inlet port and a second liquid outlet port; and
the first liquid outlet port is coupled with the second liquid inlet port.

10. The apparatus of claim 1, wherein the field replaceable electronic component is a memory module and the heat conductor is a heat pipe.

11. The apparatus of claim 1, wherein the heat conductor extends from the field replaceable electronic component.

12. The apparatus of claim 1, wherein the cooling component is a liquid cooling block and the connector is a clamp having a first, closed end, coupled with the liquid cooling block and a second, open end, opposite the first end, to removably receive the heat conductor and provide an inward clamping force orthogonal to a direction of insertion of the heat conductor from the open end to the closed end.

13. The apparatus of claim 12, wherein the clamp is a u-shaped channel structured to thermally couple a first side of the heat conductor with a first inner side of the u-shaped channel and a second side of the heat conductor with a second inner side of the u-shaped channel.

14. The apparatus of claim 13, wherein the inward clamping force is to compress a thermal interface material between the first side of the heat conductor and the first inner side, and between the second side of the heat conductor and the second inner side.

15. The apparatus of claim 1, further comprising the computer device having the electronic component inserted.

16. A computer device comprising:
a networking interface;
a processor coupled with the networking interface;
an electronic component coupled with the processor, wherein the electronic component is field replaceable;
a receptacle to removably receive and electrically couple the field replaceable electronic component;
a cooling component coupled with an existing cooling system; and
a connector coupled and in contact with the cooling component, wherein the connector is structured to removably couple the cooling component to a heat conductor of the field replaceable electronic component, and wherein the connector is structured to remain coupled with the cooling component when the field replaceable electronic component is removed.

17. The computer device of claim 16, wherein the heat conductor extends from the field replaceable electronic component and the connector is a clamp positioned to receive the heat conductor during insertion of the field replaceable electronic component into the receptacle along a plane, and structured to provide a clamping force orthogonal to the plane.

18. The computer device of claim 17, wherein the receptacle is a slot to receive a field replaceable electronic component having a card edge connector.

19. The computer device of claim 18, wherein the slot is a dual in-line memory module (DIMM) slot.

20. The computer device of claim 18, wherein the cooling component is a liquid cooling block that includes a liquid inlet port and a liquid outlet port.

21. The computer device of claim 20, wherein the liquid cooling block liquid inlet port is coupled with a computer device liquid inlet port and the liquid cooling block liquid outlet port is coupled with a computer device liquid outlet port.

22. A field replaceable electronic device comprising:
a device connector structured to be removably accepted into a receptacle of a motherboard along a plane; and
a heat conductor structured to be received by a cooling connector that is to removably couple, with a clamping force orthogonal to the plane, the heat conductor to a cooling component coupled with an existing cooling system, wherein the heat conductor is a heat pipe.

23. The field replaceable electronic device of claim 22, wherein the device connector is a card edge connector, the heat conductor extends from the field replaceable electronic device, the cooling connector is a clamp, and the cooling component is a liquid cooling block.

24. The field replaceable electronic device of claim 22, wherein the field replaceable electronic device is a dual inline memory module (DIMM).

25. (canceled)
